(19) United States
(12) Patent Application Publication
(10) Pub. No.: US 2026/0190540 A1
(43) Pub. Date: Jul. 2, 2026

(54) SINGLE PHOTON AVALANCHE DIODE WITH SHARED CONDUCTIVE LINE

(71) Applicant: GlobalFoundries Singapore Pte. Ltd., Singapore (SG)

(72) Inventors: Francesco GRAMUGLIA, Augsburg (DE); Eng Huat TOH, Singapore (SG)

(21) Appl. No.: 19/008,268

(22) Filed: Jan. 2, 2025

(51) Int. Cl. H10F 77/00; H10F 30/221; H10F 30/225; H10F 39/10; H10F 71/10

(52) U.S. Cl. CPC H10F 77/933; H10F 30/221; H10F 30/225; H10F 39/107; H10F 71/10

(57) ABSTRACT

A single-photon avalanche diode (SPAD) device includes a first deep trench isolation (DTI) structure on a first side of the SPAD device, a first vertical doped region over a side of the first DTI structure, a second DTI structure on a second side of the SPAD device, a second vertical doped region over a side of the second DTI structure, a deep well coupled between the first vertical doped region and the second vertical doped region, and a shallow trench structure over the second DTI structure, the shallow trench structure comprising insulating sidewalls and a first conductive line between the insulating sidewalls, wherein the first conductive line is coupled to the second vertical doped region.

### BACKGROUND

Photodetectors are sensors that detect the presence of electromagnetic radiation. Semiconductor photodiodes are a category of photodetectors that use a P-N diode to convert incident photons into current. Photodiodes are used by many different technologies to sense one or more frequency of light, to determine the time at which transmitted light is reflected back to the photodiode, etc.

Avalanche photodiodes are a highly biased photodiodes in which photo-generated carriers are multiplied by avalanche breakdown in the device. Single-photon avalanche diodes (SPADs) are avalanche photodiodes which are sensitive enough to detect the incidence of a single photon, and have lower timing jitter than typical photodiodes.

Conventional avalanche photodiodes tend to be relatively complex structures that are difficult to fabricate, and the layout of conventional photodiodes limits their fill factor.

### SUMMARY

Embodiments of the present application relate to a single-photon avalanche diode (SPAD) device, an array of SPAD devices, and a method for forming an SPAD device.

According to at least some of the embodiments disclosed herein, a SPAD device includes a first deep trench isolation (DTI) structure on a first side of the SPAD device, a first vertical doped region over a side of the first DTI structure, a second DTI structure on a second side of the SPAD device, a second vertical doped region over a side of the second DTI structure, a deep well coupled between the first vertical doped region and the second vertical doped region, and a shallow trench structure over the second DTI structure, the shallow trench structure comprising insulating sidewalls and a first conductive line between the insulating sidewalls, wherein the first conductive line is coupled to the second vertical doped region.

According to at least some of the embodiments disclosed herein, an array of SPAD devices includes a plurality of SPAD devices, and each SPAD device of the array of SPAD devices includes a first DTI structure on a first side of the SPAD device, a first vertical doped region over a side of the first DTI structure, a second DTI structure on a second side of the SPAD device, a second vertical doped region over a side of the second DTI structure, a deep well coupled between the first vertical doped region and the second vertical doped region, and a shallow trench structure over the second DTI structure, the shallow trench structure comprising insulating sidewalls and a first conductive line between the insulating sidewalls, wherein the first conductive line is coupled to the second vertical doped region.

According to at least some of the embodiments disclosed herein, a method for forming an SPAD device includes forming a first DTI structure on a first side of the SPAD device, forming a second DTI structure on a second side of the SPAD device, forming a first vertical doped region over a side of the first DTI structure, forming a second vertical doped region over a side of the second DTI structure, forming a deep well coupled between the first vertical doped region and the second vertical doped region, and forming a shallow trench structure over the second DTI structure, the shallow trench structure comprising insulating sidewalls and a conductive line between the insulating sidewalls, wherein the conductive line is coupled to the second vertical doped region.

### BRIEF DESCRIPTION OF THE DRAWINGS

FIG. 1 illustrates a plan view of an embodiment of four SPAD devices.

FIG. 2 is a cross-sectional view of the SPAD devices of FIG. 1.

FIGS. 3A to 3E illustrate an embodiment of a process for forming an SPAD device.

FIG. 4 illustrates an embodiment of an array of SPAD devices.

FIG. 5 is a cross-sectional view of another embodiment of SPAD devices.

### DETAILED DESCRIPTION

A detailed description of embodiments is provided below along with accompanying figures. The scope of this disclosure is limited by the claims and encompasses numerous alternatives, modifications and equivalents. Although steps of various processes are presented in a given order, embodiments are not necessarily limited to being performed in the listed order. In some embodiments, certain operations may be performed simultaneously, in an order other than the described order, or not performed at all.

Numerous specific details are set forth in the following description. These details are provided to promote a thorough understanding of the scope of this disclosure by way of specific examples, and embodiments may be practiced according to the claims without some of these specific details. Accordingly, the specific embodiments of this disclosure are illustrative, and are not intended to be exclusive or limiting. For the purpose of clarity, technical material that is known in the technical fields related to this disclosure has not been described in detail so that the disclosure is not unnecessarily obscured. The figures are not drawn to scale, and various features are enlarged or diminished for visual clarity.

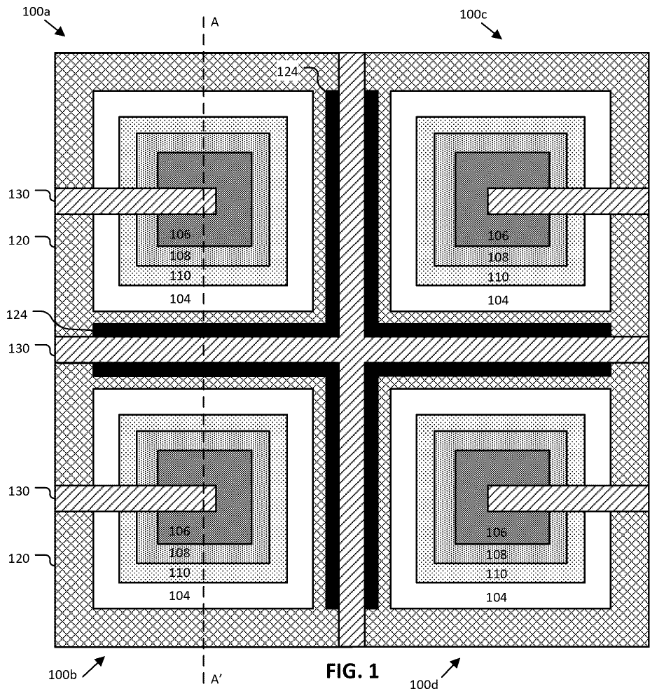

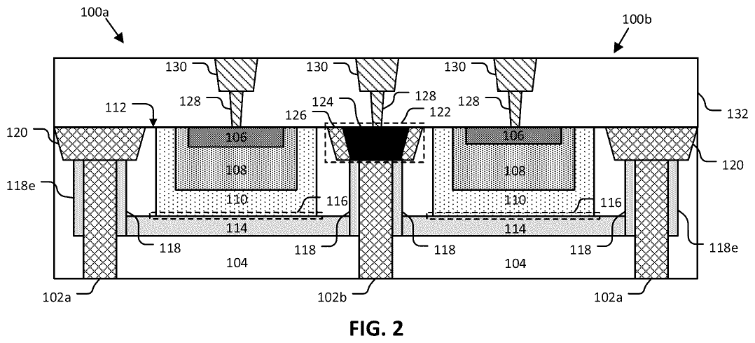

FIG. 1 illustrates a plan view of an array of four single-photon avalanche photodiode (SPAD) devices 100 according to an embodiment, and FIG. 2 illustrates a cross-sectional view of two of the SPAD devices 100a and 100b taken along A-A′ of FIG. 1.

Referring to FIG. 2, each SPAD device 100 comprises a first deep trench isolation (DTI) structure 102a and a second DTI structure 102b, each of which are filled with an insulation material such as silicon oxide and electrically isolate conductive structures of an SPAD device 100 from an adjacent SPAD device 100. In an embodiment in which SPAD devices 100 are adjacent to one another as seen in FIG. 2, the second DTI structure 102b may be shared by a first SPAD device 100a and a second SPAD device 100b.

Each SPAD device 100 comprises a highly doped region 106 adjacent to an incident surface 112. Here, the incident surface 112 is a surface at which light enters an active semiconductor portion of the SPAD device 100. A first doped well 108 is under the highly doped region 106, and a second doped well 110 is under the first doped well 108. The highly doped region 106, first doped well 108 and second doped well 110 may all be doped with the same type of impurities, which may be either P-type impurities or N-type impurities.

For example, when highly doped region 106 is doped with P-type impurities, the first doped well 108 and second doped well 110 may also be doped with P-type impurities, and when highly doped region 106 is doped with N-type impurities, the first doped well 108 and second doped well 110 may also be doped with N-type impurities. Exemplary dopant concentrations for the highly doped region 106 are on the order of 1*10¹⁹/cm³ to 1*10²¹/cm³, and exemplary concentrations for the first doped well 108 and second doped well 110 are on the order of 1*10¹⁶/cm³ to 1*10¹⁸/cm³. As used herein, “on the order of” refers to an order of magnitude, such that a dopant concentration on the order of 10¹⁹/cm³ includes dopant concentrations of 1*10¹⁹/cm³ to 9*10¹⁹/cm³.

The doped wells 108 and 110 are formed in a semiconductor material 104 which may be lightly doped with the same type of impurities as the highly doped region 106, first doped well 108 and second doped well 110.

A deep well 114 is below the second doped well 110. The deep well 114 is doped with a different type of impurities from the doped wells 108 and 110, and a PN junction or diode 116 is present between the deep well 114 and the second doped well 110. The deep well 114 may have an impurity concentration that is similar to that of the second doped well 110, e.g. on the order of 1*10¹⁶/cm³ to 1*10¹⁸/cm³.

The deep well 114 extends between and is electrically coupled to vertical doped regions 118 which are on sides of the DTI structures 102. The vertical doped regions 118 may be present over both sides of each DTI structure 102, e.g. present at each side of the trench that is filled to form the DTI structures 102. As explained below, the vertical doped regions 118 may be formed by doping sidewalls of an open trench used to form the DTI structures 102. Accordingly, vertical doped regions 118 may be characterized as doped sidewalls of a DTI structure 102, in which case the sidewalls are the sidewalls of a trench of the DTI structure 102.

The vertical doped regions 118 are doped with the same type of impurities as deep well 114, but may have a higher concentration. For example, the vertical doped regions 118 may have an N+ or P+ doping with an impurity concentration on the order of 1*10¹⁹/cm³ or greater. For example, the vertical doped regions 118 may have an impurity concentration on the order of 1*10¹⁹/cm³ to 1*10²¹/cm³.

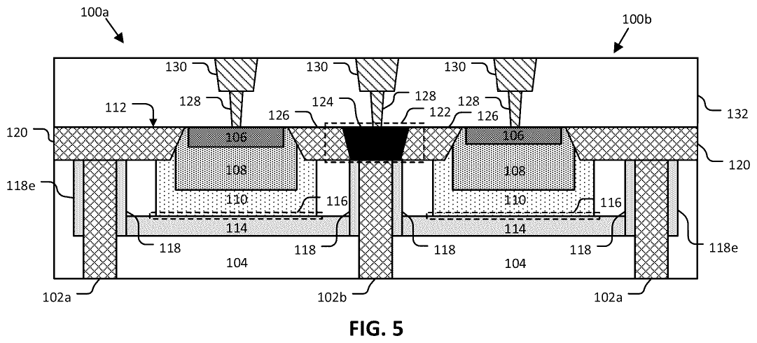

A shallow trench isolation (STI) structure 120 is disposed over the first DTI structure 102a. The STI structure 120 comprises a shallow trench filled with an insulating material such as an oxide (e.g. silicon oxide). The STI structure 120 may have a width that is wider than the first DTI structure 102a and extend over the vertical doped regions 118 adjacent to the first DTI structure 102a. In some embodiments, the STI structure 120 may cover a substantial portion of the incident surface 112 of an SPAD device 100. Such an embodiment is explained in more detail below with respect to FIG. 5

A shallow trench structure 122 is disposed over the second DTI structure 102b. The shallow trench structure 122 comprises a conductive line 124 which may comprise a doped semiconductor material, e.g. a doped polysilicon, although other conductive materials are possible. For example, in another embodiment, the conductive line 124 may comprise a metal material and a liner material (not shown). The conductive line 124 may be located in the center of the shallow trench structure 122 and may extend between the incident surface 112 and the base of the shallow trench to provide a conductive path to vertical doped regions 118 on both sides of the second DTI structure 102b. Accordingly, the conductive line 124 may extend over and contact a top portion of the vertical doped regions 118 at sides of the second DTI structure 102b.

The conductive line 124 may be doped with the same type of impurities as the vertical doped regions 118 and may have a similar impurity concentration. For example, the conductive line 124 may have an impurity concentration on the order of 1*10¹⁹/cm³ or greater. For example, the conductive line 124 may have an impurity concentration on the order of 1*10¹⁹/cm³ to 1*10²¹/cm³.

In addition, the conductive line 124 may be part of an anode or cathode of the two adjacent SPAD devices 100a and 100b in FIG. 2. When the conductive line 124 is doped polysilicon, its role as an anode or cathode may correspond to a type of impurities. For example, when the conductive line 124 is polysilicon doped with N type impurities, the conductive line may be part of a cathode, and when the conductive line 124 is polysilicon doped with P type impurities, the conductive line may be part of an anode. Other components of an anode or cathode which comprises the conductive line 124 include vertical doped regions 118 and deep well 114.

The shallow trench structure 122 also comprises insulating sidewalls 126 on both sides of the shallow trench. The insulating sidewalls 126 may comprise one or more insulating material such as silicon oxide. In some embodiments, the insulating material of insulating sidewalls 126 is the same insulating material of STI structures 120. The insulating sidewalls 126 may electrically isolate adjacent SPAD devices 100 and may also provide a dielectric barrier between the conductive line 124 and doped regions of an SPAD device 100, e.g. highly doped region 106 and doped wells 108 and 110.

The conductive line 124 is coupled to a metal line 130 by a contact 128, and the highly doped region 106 is coupled to another metal line 130 by another contact 128. The contacts 128 and metal lines 130 may comprise typical metal materials as known in the art, e.g. tungsten, copper or aluminum, as well as one or more liner material (not shown). The metal lines 130 that extend over the SPAD devices 100 may be in back end of line (BEOL) metal level M1 as depicted in the figures or a different metal level, e.g. M2 or M3. Interconnect structures including metal lines 130, contacts 128 and vias (not shown) may be arranged in various ways in different embodiments to bias the SPAD devices 100 without departing from the scope of the present disclosure.

In embodiments of the present disclosure, a single contact 128 may be used to bias two adjacent SPAD devices (e.g. a first SPAD device 100a and a second SPAD device 100b as shown in FIG. 2) through a single conductive line 124. Accordingly, embodiments of the present disclosure include a contact 128 and conductive line 124 which are shared between two adjacent SPAD devices 100. In contrast, conventional devices use a contact to bias each respective deep well. Therefore, while conventional devices typically use four contacts to bias adjacent SPAD devices, embodiments of the present disclosure may only use three contacts 128 to bias two adjacent SPAD devices 100, which reduces the complexity and increases the fill factor compared to conventional devices.

Vertical doped regions 118e at outer edges of an array of SPAD devices 100 and not coupled to deep wells 114 may not be biased. For example, the vertical doped regions 118e at the far left and right sides of FIG. 2, which correspond to outer edges of the four-SPAD array shown in FIG. 1, are not coupled to any contacts or doped wells. Those vertical doped regions 118e may be formed along with active vertical doped regions 118 for convenience of manufacturing, but they are not biased when operating an array of SPAD devices 100. Accordingly, an array of SPAD devices 100 may be positioned close to active structures such as transistors without interfering with the performance of the active structures.

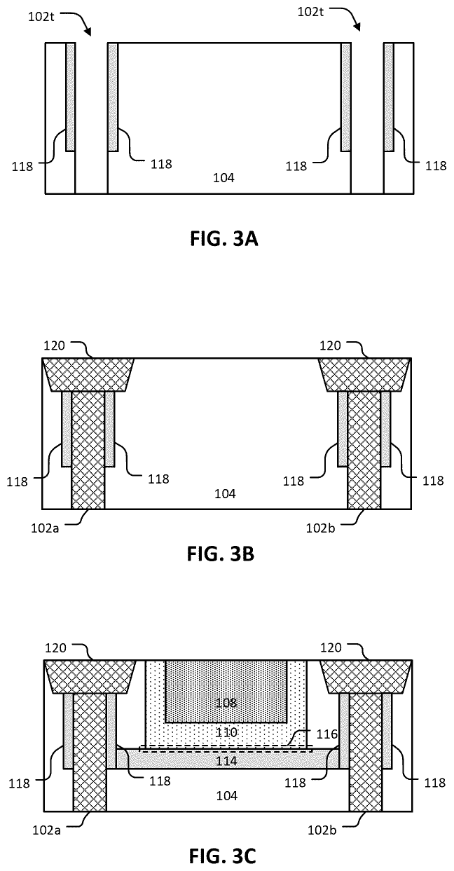

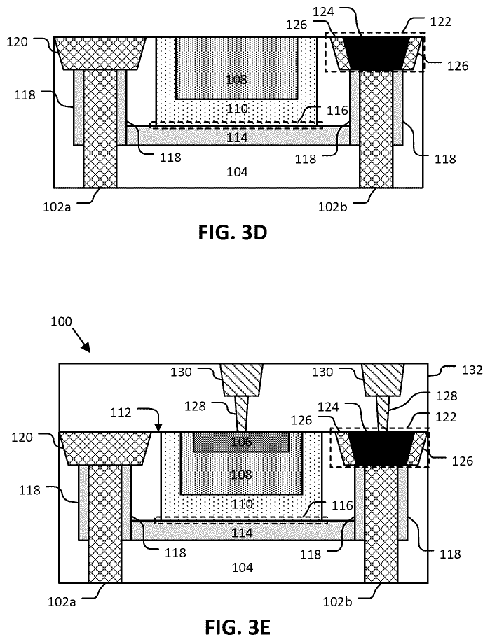

FIGS. 3A to 3E illustrate an example of a process for forming an SPAD device 100. As seen in FIG. 3A, trenches 102t are etched in a lightly doped semiconductor material 104. The trenches 102t may be formed using a typical mask and etch process as known in the art. After opening the trenches, impurities are implanted into the sidewalls of the trenches 102t using a process as known in the art, for example, an angled implantation process, to form vertical doped regions 118 on both sidewalls of the trenches 102t.

As seen in FIG. 3B, the trenches 102t are filled with an insulating material to form first and second DTI structures 102a and 102b, and STI structures 120 are formed over the DTI structures 102a and 102b. The DTI structures 102 and STI structures 120 may be formed using various materials and processes in different embodiments.

For example, in some embodiments, the DTI structures 102 and STI structures 120 may both be formed of a tetraethyl orthosilicate (TEOS) material. In such an embodiment, the openings for the STI structures 102 may be formed above open trenches 102t using a second mask and etch process, and the TEOS material may be deposited using a chemical vapor deposition (CVD) process to fill the openings followed by a planarization process such as chemical mechanical planarization (CMP), resulting in the structure shown in FIG. 3B.

In other embodiments, the material of STI structures 120 is different from the material of the DTI structures 102. In such embodiments, the DTI material is deposited into trenches 102t, and a second mask and etching process is performed to form STI openings which extend into the filled trenches 102t. The STI material, e.g. a different oxide from the DTI material, is then deposited into the STI openings and planarization is performed to form the structure shown in FIG. 3B. Accordingly, the STI structures 120 may be formed of the same material as DTI structures 102 or a different material.

Next, a series of implantation processes are performed to form deep well 114, first deep well 108 and second deep well 110. Deep well 114 may be formed by implanting dopants of a first type (N or P) into the semiconductor material 104, and first doped well 108 and second doped well 110 may be formed by implanting dopants of a second type (opposite to the first type) into the semiconductor material 104. The first doped well 108 and second doped well 110 may have the same type of impurities (e.g. a second type) as the semiconductor material 104. The PN junction 116 is formed at the interface of the second doped well 110 and the deep well 114. Each of the implantation processes may be performed using implantation techniques as known in the art.

As illustrated in FIG. 3D, a shallow trench structure 122 comprising a conductive line 124 and insulating sidewalls 126 on both sides of the shallow trench structure 122 is formed over the second DTI structure 102b. The shallow trench structure 122 may be formed using various materials and processes in different embodiments. For example, the conductive line 124 may be formed by etching an opening in an oxide material of the STI structure 120 of the previous step of FIG. 3C and filling the opening with a conductive material. The conductive material may be, for example, a metal material such as tungsten, an in-situ doped polysilicon material, or a polysilicon material that is deposited into the opening and doped with impurities in a separate operation. In an embodiment in which the conductive material of conductive line 124 is doped polysilicon, the polysilicon may be doped with the same type of impurities as the vertical doped regions 118 and deep well 114, e.g. the first type of impurities.

In some embodiments, the highly doped region 106 is formed after forming the shallow trench structure 122 as seen in FIG. 3E. The highly doped region 106 may be formed by implanting a high concentration of impurities of the second type into the first doped well 108. After forming the highly doped region 106, additional structures (not shown) may be formed on incident surface 112 such as an anti-reflective coating, a sealing layer, a protective layer, etc. Next, contacts 128 may be formed by depositing an insulating material 132 over the incident surface 112 and forming contacts in the insulating material 132 using a damascene process. The contacts 128 may comprise a liner material (not shown) and a metal material as known in the art. Metal lines 130 may be formed over the contacts 128 using typical BEOL processes, e.g. depositing and planarizing additional insulation material 132 over the contacts 128, and forming the metal lines 130 using a damascene process. The metal lines may comprise a liner material (not shown).

While the process steps of FIGS. 3A to 3E have been described with respect to forming a single SPAD device 100, similar processes may be used to form an array of SPAD devices 100. In some embodiments, a single semiconductor device may comprise one or more array of tens, hundreds or thousands of SPAD devices 100.

FIG. 1 shows an embodiment of an array of four SPAD devices 100a, 100b, 100c and 100d. In the embodiment of FIG. 1, two orthogonal conductive lines 124 are arranged in a “+” shape, and each conductive line 124 may be an anode or a cathode for all four SPAD devices 100. For example, the SPAD device 100a comprises one (vertical in FIG. 1) conductive line 124 across one side of the device and another (horizontal in FIG. 1) conductive line 124 across another side of the device. Conductive lines 124 are comprised in shallow trench structures 122, so it should be understood that each SPAD device 100 in the array of FIG. 1 also comprises shallow trench structures 122 along two sides of the respective device 100.

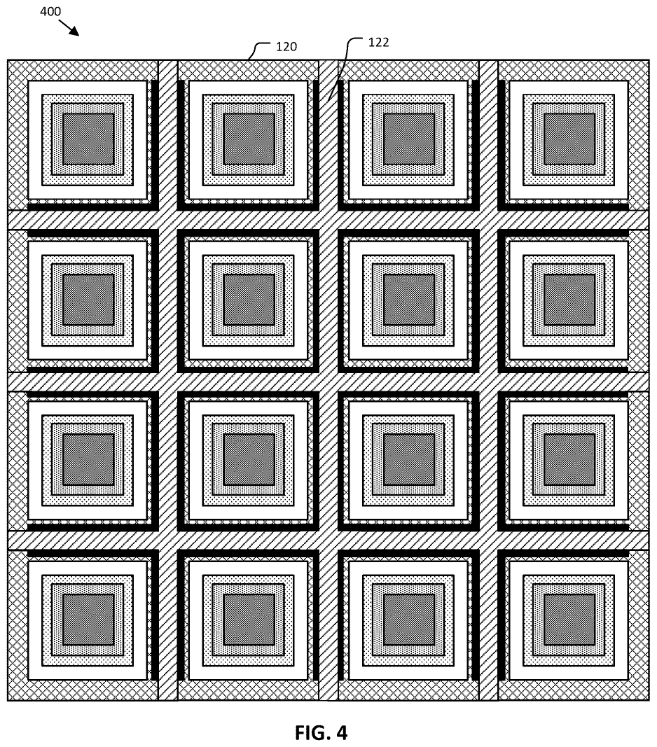

FIG. 4 illustrates another example of an array 400 of 16 SPAD devices 100. A larger array of SPAD devices may be arranged in a similar fashion, e.g. by extending shallow trench structures 122 across additional SPAD devices 100. BEOL Metal lines are not shown in FIG. 4 for visual clarity. In the embodiment of FIG. 4, central SPAD devices 100 comprise shallow trench structures 122 on four sides, and SPAD devices on the periphery of the array 400 comprise shallow trench structures 122 on three sides, or on two sides in the case of SPAD devices in the corners. The remaining sides of the SPAD devices 100 on the periphery of the array 400 comprise STI structures 120 over first DTI structures 102a. Accordingly, an SPAD device 100 according to an embodiment of the present disclosure may comprise two, thee or four shallow trench structures 122 respectively disposed over DTI structures 102 on sides of the device.

FIG. 5 shows another embodiment of two adjacent SPAD devices 100a and 100b. The embodiment of FIG. 5 is similar to that of FIG. 2, except that shallow trench isolation structures cover larger portions of the incident surface 112. In particular, the STI structures 120 and insulating sidewalls 126 of the embodiment of FIG. 5 are enlarged in the horizontal dimension compared to the same structures in the embodiment of FIG. 2.

In various embodiments, the STI structures 120 and shallow trench structures 122 may extend over 20%, 40%, 60%, 80% or more of the distance between first DTI structure 102a and second DTI structure 102b at the incident surface 112 of an SPAD device 100. In such embodiments, the STI structures 120 and shallow trench structures 122 may be formed after performing implantation processes to form one or more of the highly doped region 106, first doped well 108, second doped well 110 and deep well 114.

Embodiments of the present disclosure have numerous possible advantages over conventional devices. For example, embodiments of the present disclosure may have a greater fill factor than conventional devices. Shallow trench structures 122 may be shared by two adjacent SPAD devices 100, reducing the amount of conductive structures used to bias the devices. In addition, vertical doped regions 118 may be formed by doping vertical trenches of DTI structures 102, so the width of vertical doped regions 118 may be less than that of conventional devices. For example, the width of vertical doped regions 118 may be from 80 nm to 200 nm, while similar structures in conventional devices may have a width of about 600 nm. As a result, the width of second doped well 110 in an embodiment of the present disclosure may be substantially larger than that of a conventional device, e.g. around one micron larger in some implementations. These and other advantages will be apparent to a person of ordinary skill in the art in view of the present disclosure.

Aspects of the present disclosure have been described in conjunction with the specific embodiments thereof that are proposed as examples. Numerous alternatives, modifications, and variations to the embodiments as set forth herein may be made without departing from the scope of the claims set forth below. Accordingly, embodiments as set forth herein are intended to be illustrative and not limiting. Steps within a method claim are not limited to the order in which they appear in the claim. For example, in a method claiming forming a first structure followed by forming a second structure, the second structure may be formed before the first structure within the scope of the claim. That is, no sequential order is necessarily implied by the order in which steps are listed.

1. A single-photon avalanche diode (SPAD) device comprising:
a first deep trench isolation (DTI) structure on a first side of the SPAD device;
a first vertical doped region over a side of the first DTI structure;
a second DTI structure on a second side of the SPAD device;
a second vertical doped region over a side of the second DTI structure;
a deep well coupled between the first vertical doped region and the second vertical doped region; and
a shallow trench structure over the second DTI structure, the shallow trench structure comprising insulating sidewalls and a first conductive line between the insulating sidewalls, wherein the first conductive line is coupled to the second vertical doped region.

2. The SPAD device of claim 1, wherein the first conductive line comprises a doped polysilicon material.

3. The SPAD device of claim 1, wherein a width of the first conductive line is greater than a width of the second DTI structure.

4. The SPAD device of claim 1, further comprising:
a third DTI structure on a third side of the SPAD device; and
a second shallow trench structure over the third DTI structure, the second shallow trench structure comprising insulating sidewalls and a second conductive line between the insulating sidewalls.

5. The SPAD device of claim 1, further comprising a first shallow trench isolation (STI) structure over the first DTI structure.

6. The SPAD device of claim 5, wherein a trench of the first STI structure is filled with an insulating material.

7. The SPAD device of claim 1, further comprising:
a second shallow trench structure over the first DTI structure, the second shallow trench structure comprising insulating sidewalls and a second conductive line between the insulating sidewalls.

8. The SPAD device of claim 1, further comprising:
a highly doped region at an incident surface of the SPAD device;
a first doped well under the highly doped region; and
a second doped well under the first doped well.

9. The SPAD device of claim 8, further comprising a PN junction between the second doped well and the deep well.

10. The SPAD device of claim 1, wherein the first conductive line is part of an anode or a cathode of the SPAD device.

11. The SPAD device of claim 10, wherein the first conductive line is part of an anode or a cathode of a second SPAD device adjacent to the SPAD device.

12. The SPAD device of claim 1, wherein the first conductive line is coupled to a metal line in a back end of line (BEOL) level by a single contact.

13. An array of single-photon avalanche diode (SPAD) devices, each SPAD device of the array of SPAD devices comprising:
a first deep trench isolation (DTI) structure on a first side of the SPAD device;
a first vertical doped region over a side of the first DTI structure;
a second DTI structure on a second side of the SPAD device;
a second vertical doped region over a side of the second DTI structure;
a deep well coupled between the first vertical doped region and the second vertical doped region; and
a shallow trench structure over the second DTI structure, the shallow trench structure comprising insulating sidewalls and a conductive line between the insulating sidewalls, wherein the conductive line is coupled to the second vertical doped region.

14. The array of claim 13, wherein the conductive line comprises a doped polysilicon material.

15. The array of claim 13, wherein a width of the conductive line is greater than a width of the second DTI structure.

16. The array of claim 13, wherein each SPAD device of the array of SPAD devices further comprises:
a third DTI structure on a third side of the SPAD device; and
a second shallow trench structure over the third DTI structure, the second shallow trench structure comprising insulating sidewalls and a second conductive line between the insulating sidewalls.

17. The array of claim 13, wherein each SPAD device of the array of SPAD devices further comprises a first shallow trench isolation (STI) structure over the first DTI structure.

18. The array of claim 13, wherein the array of SPAD devices comprises a first SPAD device and a second SPAD device, and
wherein the first conductive line is part of an anode or a cathode of both the first SPAD device and the second SPAD device.

19. The array of claim 13, wherein each SPAD device of the array of SPAD devices further comprises:
a highly doped region at an incident surface of the SPAD device;
a first doped well under the highly doped region;
a second doped well under the first doped well; and
a PN junction between the second doped well and the deep well.

20. A method for forming a single-photon avalanche diode (SPAD) device, the method comprising:
forming a first deep trench isolation (DTI) structure on a first side of the SPAD device;
forming a second DTI structure on a second side of the SPAD device;
forming a first vertical doped region over a side of the first DTI structure;
forming a second vertical doped region over a side of the second DTI structure;
forming a deep well coupled between the first vertical doped region and the second vertical doped region; and
forming a shallow trench structure over the second DTI structure, the shallow trench structure comprising insulating sidewalls and a conductive line between the insulating sidewalls, wherein the conductive line is coupled to the second vertical doped region.
